(19) United States
(12) Patent Application Publication
(10) Pub. No.: US 2024/0332078 A1
(43) Pub. Date: Oct. 3, 2024

(54) POST-LASER DICING WAFER-LEVEL TESTING

(71) Applicant: TEXAS INSTRUMENTS INCORPORATED, DALLAS, TX (US)

(72) Inventors: Michael T. WYANT, DALLAS, TX (US); Joseph O. LIU, DALLAS, TX (US); Christopher MANACK, DALLAS, TX (US)

(21) Appl. No.: 18/194,126

(22) Filed: Mar. 31, 2023

(51) Int. Cl. H01L 21/78; H01L 21/268; H01L 21/304; H01L 21/66; H01L 21/683

(52) U.S. Cl. CPC H01L 21/78; H01L 21/268; H01L 21/304; H01L 21/6836; H01L 22/12

(57) ABSTRACT

In a described example, a method includes thinning a first side of a semiconductor substrate, in which a plurality of dies are formed on a second side of the substrate opposite the first side and separated from each other by scribe streets of the substrate. The method also includes directing a laser beam at the first side with an entry point along a scribe street thereof, in which the laser beam is focused inside the substrate to form at least one modified region within the substrate at a location spaced apart from the first side and at least one crack propagates from the modified region toward the first side. The method also includes electrically testing the dies on the substrate, in which the dies being tested are located between the modified regions of respective scribe streets of the substrate.

### TECHNICAL FIELD

This description relates to systems and methods for implementing wafer-level testing after laser dicing.

### BACKGROUND

Die preparation is a part of the semiconductor device fabrication process in which a wafer is prepared for integrated circuit (IC) packaging and testing. The process of die preparation generally includes wafer dicing. Prior to wafer dicing, the wafer is mounted on a tape (e.g., dicing tape). A wafer dicing process is used to separate individual die from a wafer of semiconductor, while mounted to the dicing tape. The dicing process can involve scribing and breaking, mechanical sawing or laser cutting. Once a wafer has been diced, the dies will stay on the dicing tape until they are extracted by die-handling equipment, such as a die bonder or die sorter, later in the packaging process.

### SUMMARY

In a described example, a method includes thinning a first side of a semiconductor substrate, in which a plurality of dies are formed on a second side of the substrate opposite the first side and separated from each other by scribe streets of the substrate. The method also includes directing a laser beam at the first side with an entry point along a scribe street thereof, in which the laser beam is focused inside the substrate to form at least one modified region within the substrate at a location spaced apart from the first side and at least one crack propagates from the modified region toward the first side. The method also includes electrically testing the dies on the substrate, in which the dies being tested are located between the modified regions of respective scribe streets of the substrate.

In another described example, a method includes directing a laser beam at a first surface of a semiconductor substrate with an entry point along a scribe street thereof, in which the laser beam is focused inside the substrate to form at least one modified region within a respective layer of the substrate at a location spaced apart from the first surface and at least one crack propagates from the modified region toward the first surface. The method also includes removing tape from a second surface of the substrate that is opposite the first surface and electrically testing a plurality of dies on the substrate, in which the dies being tested are located between the modified regions of respective scribe streets of the substrate.

In another described example, a semiconductor device includes a semiconductor die, in which the semiconductor die includes an integrated circuit in a semiconductor substrate. The semiconductor die has a sidewall extending between the first and second surfaces, a first surface region of the sidewalls extending from the first surface to an intermediate location has a first texture, and a second surface region extending from the intermediate location toward the second surface has a second texture that is smoother than the first texture.

### BRIEF DESCRIPTION OF THE DRAWINGS

FIG. 1 is a flow diagram depicting an example die separation method that can be used to form semiconductor apparatus.

FIGS. 2A, 2B, 3, 4, 5, 6, 7A, 7B, 7C, 8 & 9 are cross-sectional views of a semiconductor device being processed according to the method of FIG. 1.

FIG. 10 is a side view of a semiconductor die showing an example of textures along a sidewall of the die.

### DETAILED DESCRIPTION

This description relates to methods of semiconductor fabrication that include wafer-level testing that is implemented after laser dicing and to semiconductor devices produced by such a method. For example, a method includes performing stealth laser dicing, such as by directing a laser beam at a first side of semiconductor substrate (e.g., wafer) with an entry point along a scribe street thereof. One or more integrated circuits are on a second (e.g., top or front) side of the substrate, which is opposite to the first side where the laser beam is directed. The laser beam can be focused inside the substrate to form at least one modified region within the substrate at a location spaced apart from the first side. At least one crack propagates within the substrate from the modified region toward the first side of the substrate. Cracks can also propagate from the modified region toward the second side of the substrate. After laser dicing, the dies on the substrate are electrically tested such as by testing equipment having an arrangement of probes or needles configured to contact pads on each die. Thus, each die being tested is located between the modified regions and associated cracks of respective scribe streets of the substrate.

The method can further include separating the dies from each other along the cracks and through respective modified regions that have been formed in the respective scribe streets. For example, tape (e.g., backgrind tape) is applied to the second side of the substrate, and the first side is thinned, such as by using a surface grinder or grinding wheel to backgrind the substrate. The backgrinding can remove a sufficient amount from the first side of the substrate to cause the dies to be separated. In an example, the backgrinding is performed to remove a portion of the substrate sufficient to remove the cracks in the substrate between the first side and the modified region. As a result, the sidewall surfaces of the respective dies each has a modified texture along a first sidewall surface region extending from the first surface to an intermediate location. The modified texture is provided responsive to separating adjacent dies through the modified region. The sidewall surfaces of the respective dies also have different textures along a second sidewall surface region extending from the intermediate location toward the second surface. The different texture, for example, is responsive to separating adjacent dies through a crack.

A dicing tape can be applied to the thinned second side, and the backgrind tape can be removed from the first side so the separated dies reside on the dicing tape. The dicing tape can be expanded to space apart the respective die from one another, such as to provide a desired die-to-die gap to facilitate picking up the dies for further fabrication. The further fabrication can include a die attach operation and wire bonding with respect to a leadframe or other package structure. The resulting IC chip can be packaged in molding material, such as plastic or ceramic.

As used herein, the term semiconductor device (and its variants) refers to any structure or apparatus that includes a semiconductor substrate. For example, a semiconductor substrate (e.g., a wafer) having a plurality of integrated circuit (IC) dies formed thereon is a semiconductor device. An individual die or group of die, which may be on a wafer or separated from the wafer, is another example of a semiconductor device. Additionally, one or more dies that have been packaged in molding material is yet another example of a semiconductor device. Thus, a semiconductor device can exist at any stage of the semiconductor fabrication workflow including the resulting packaged IC chip or system on chip (SoC).

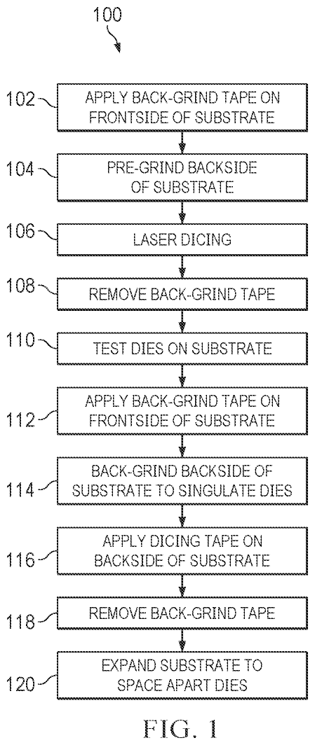

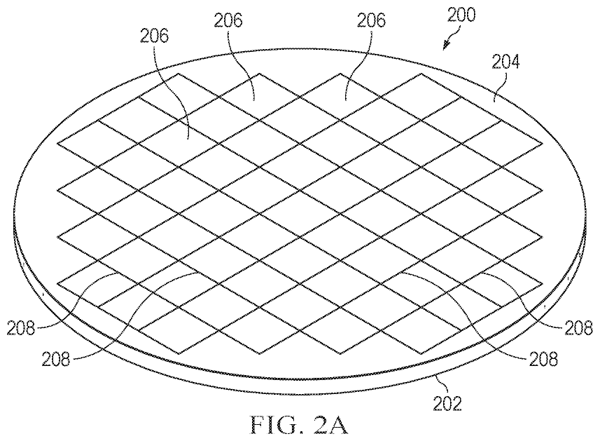

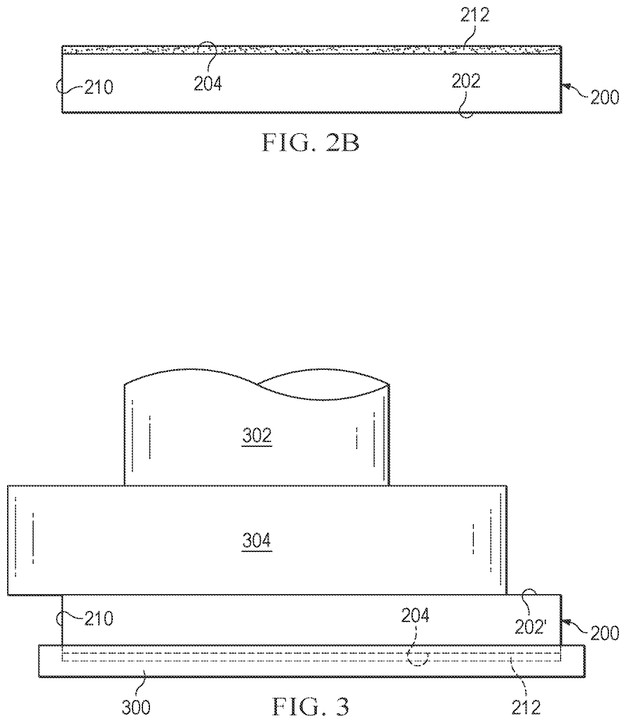

FIG. 1 is a flow diagram depicting an example method 100 that can be implemented to perform die preparation in an overall semiconductor fabrication workflow. The method 100 is described in relation to the cross-sectional views of FIGS. 2-10, which show an example processing progression of wafer preparation that can be used in a semiconductor fabrication workflow to form a semiconductor device.

At 102, a backgrind tape is applied to a side (e.g., the front or top side) of a semiconductor substrate (e.g., a wafer). For example, FIGS. 2A and 2B show an example of a semiconductor wafer 200 that includes a first and second opposing side surfaces 202 and 204 and a sidewall 210 extending between the side surfaces. The first surface 202 is a bottom side (also referred to as the back side) of the wafer 200 and the second surface 204 is a top side (also referred to as the front side) of the wafer. The wafer 200 includes a plurality of semiconductor die 206 distributed across the second surface 204. Each die 206 includes circuitry formed therein at or near the surface of the second surface 204. Each of the die 206 are spaced from one another by respective scribe streets that extend longitudinally across the wafer 200, shown at 208. Thus, respective scribe streets 208 are located between adjacent die 206.

In the example of FIG. 2B, a tape 212 is shown applied to the second side (e.g., frontside) surface 204 of the wafer 200. The tape 212 can be an ultraviolet (UV) curable grinding tape that includes one or more layers of material having an adhesive layer (e.g., a ultraviolet (UV) curable adhesive) to bond temporarily to the frontside surface 204 of the wafer 200 during subsequent grinding at 104. The tape 212 can include one or more adhesive layers that can be cured to increase adhesion to the surface 204, such as by application of energy (e.g., ultraviolet light and/or heat). The grinding at 104 can be implemented to thin the back side of the substrate while the tape 212 is affixed to the surface 204.

For example, as shown in FIG. 3, the wafer 200 is mounted on a stage 300 after the tape 212 has been applied, as shown in FIG. 2B. The stage 300 is moveable in at least two orthogonal directions parallel to the surface of the wafer 200 (e.g., to provide movement in at least two degrees of freedom). For example, the stage 300 is moveable in five degrees of freedom, such as along three orthogonal axes as well as pitch and roll directions. FIG. 3 also shows a surface grinder 302 having a grinding wheel 304 supported above the stage and configured to thin the substrate by grinding and/or polishing. In an example, the grinding at 104 can be implemented to remove less than 10% of the thickness of the substrate from the first side of the substrate, such as to remove a layer of surface oxidation from the back side surface 202. The grinder thus removes a layer of the substrate from the first side surface to provide a thinned first surface, shown at 202′.

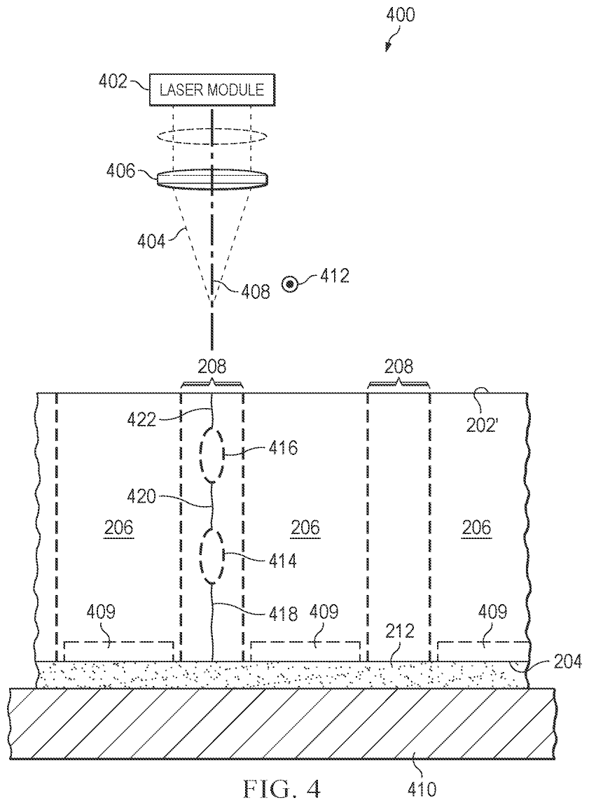

At 106, the method includes performing laser dicing of the substrate. For example, as shown in FIG. 4, laser dicing (at 106) can be implemented on the wafer 200 by a laser system 400 that includes a laser module 402 configured to generate an infrared (IR) laser beam 404 to perform stealth laser dicing. The example of FIG. 4 shows the wafer 200 in an enlarged cross-sectional view, in which each die 206 includes circuitry 409 formed therein at or near the surface 204. Each of the dies 206, including the circuitry 409, is separated from one another by a respective scribe street 208. The laser system 400 also includes an arrangement of optics, such as including one or more focusing lenses, shown as 406. The laser module 402 includes a laser light source configured to perform pulsed oscillation of laser light along an optical axis 408 while the lens 406 is adjusted (e.g., by a control system) to focus beam at a focal point located within the wafer 200 along a respective scribe street 208 (e.g., between adjacent sets of dies 206).

The wafer 200 can be supported by a stage 410 during laser dicing at 106. A distance between the lens 406 and the focal point within the wafer 200 defines a focal length. For example, the focal length can be set to different distances (by the control system) during each pass of a multi-pass stealth dicing process. As used herein, a pass refers to a movement of the laser beam once across the wafer 200 along a beam scan direction 412 within a respective scribe street 208, such as by moving the stage 410 linearly beneath the pulsed laser beam while set to a given focal length. For example, the laser beam scan direction is shown at 412 (e.g., orthogonal to the page on which FIG. 4 is presented).

As a further example, during each pass of the laser across the wafer 200, the focused beam 404 is provided with sufficient energy to cause thermal shock at a localized damage zone at the focal point within the wafer 200. The damage zone can be a volume of substrate material (e.g., silicon), which is referred to herein as a modified region (also referred to as a silicon damage region). As the pulsed beam 404 is scanned across the wafer 200, a plurality of adjacent modified regions are formed at a given depth (e.g., depending on the focal length of the beam scan and pulse rate) to provide a respective modified layer (e.g., a stealth dicing layer) within the wafer along the length of the scribe street 208. In the example of FIG. 4, two separate modified regions 414 and 416 are shown, each of which can be considered to be representative of a respective modified layer embedded within the wafer 200 during a given pass of the laser beam focused at a different depth along the scribe street 208. That is, each of the modified regions 414 and 416 is formed by generating the beam during a respective pass in which the laser beam has its focal point at or near the center of each region. For example, the modified region 414 is spaced a further distance from the surface 202′ than the modified region 416. While the modified regions 414 and 416 are shown schematically as having circular or ellipsoid shapes, the modified regions typically have more unstructured shapes according to the crystalline structure and interaction between the beam 404 and substrate materials.

The modified region 414 further from the surface 202′ results from a first pass of the laser beam 404 and is embedded within a thickness of the wafer 200 to form an embedded crack line 418 extending from the modified region 414 toward the second side surface 204. The other modified region 416 can be formed during either the first pass (e.g., by changing the focal length) or during a second pass of the laser beam 404, in which the focal point of the laser beam is offset from the first pass focal point in a direction orthogonal to the modified region 414 towards the surface 202′. The energy of the laser during each pass can be set depending on the type and configuration of the laser and the thickness of the wafer, for example. The second pass of the laser results in a second crack line 420 such as extending vertically and connecting modified regions 414 and 416 and shallower (e.g., closer to the surface 202′) as compared to the embedded crack line 418. The second crack line 420 can be formed as an extension of a portion of a crack formed responsive to forming the modified region 414. A third crack line 422 can also extend from the modified region 416 towards and, in some examples, intersecting the surface 202′.

Referring back to FIG. 1, after laser dicing at 106, the method proceeds to 108 in which the backgrind tape (applied at 102) is removed. For example, the tape can be peeled from the surface 204, such as manually or through an automated peeling process. At 110, the dies on the substrate are tested. For example, as shown schematically in FIG. 5, the laser-diced wafer (e.g., without tape) is transferred to a wafer testing system 500. The wafer testing system 500 can include a chuck 502 configured to support the wafer 200 (e.g., a device under test) during testing the wafer testing system 500 can also include automated test equipment (e.g., a tester) 504 and one or more probe cards 506. The wafer testing system 500 can also include a motion system (not shown), such as a combination of any of mechanical actuators, robotic arms, or the like, configured to control the relative position of the chuck 502 and/or the probe card 506 in two- or three-dimensional space. For example, each probe card 506 includes one or more probe heads having an arrangement of needles (e.g., also referred to as pins) 508 extending outwardly from the probe head toward the surface 204 of the wafer 200. The probe card 506 can be coupled to the test equipment 504 configured to control testing of the wafer 200 that is supported by the chuck 502. The needles 508 can be configured to test one or more dies concurrently. For example, the needles can be arranged in a two-dimensional array and configured to contact respective conductive pads (e.g., copper, aluminum or other conductive materials) exposed along the surface 204 of the wafer 200 at test locations for each of the respective die. The conductive pads can be coupled (e.g., through electrical connections through metallization structures of the wafer 200) to on-die test circuitry. In some examples, a plurality of dies can be tested in a single touch-down event because the probe card and associated needles 508 can be “fanned out” across multiple dies. Because the electrical testing of the IC devices in the wafer are performed after laser dicing and on the full thickness of the wafer (e.g., less a small amount of material removed by pre-grinding at 104), the testing can help ensure high-quality robustness against low-level laser scattering or splashing defects that might result from the laser dicing at 106.

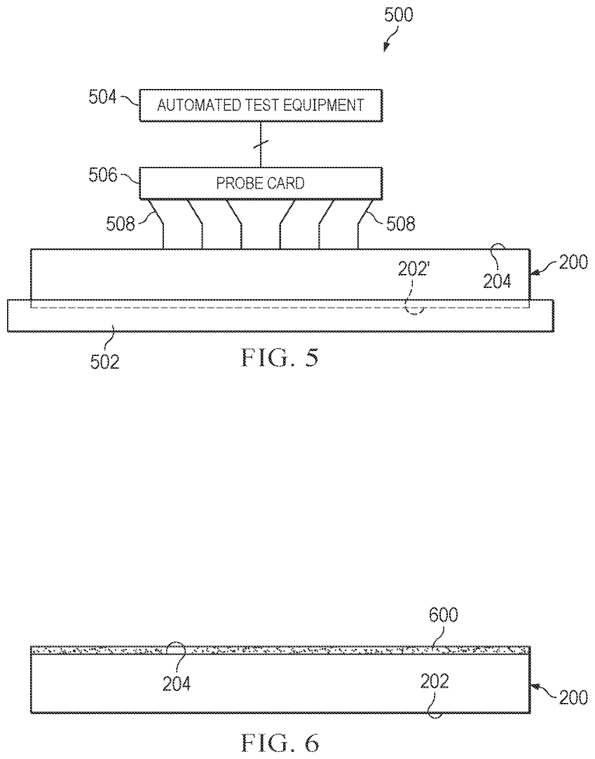

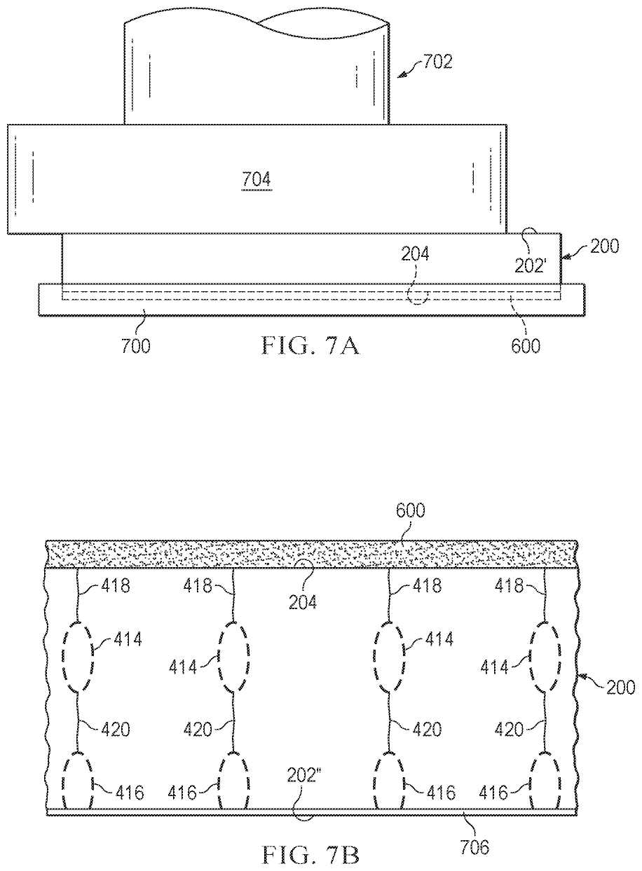

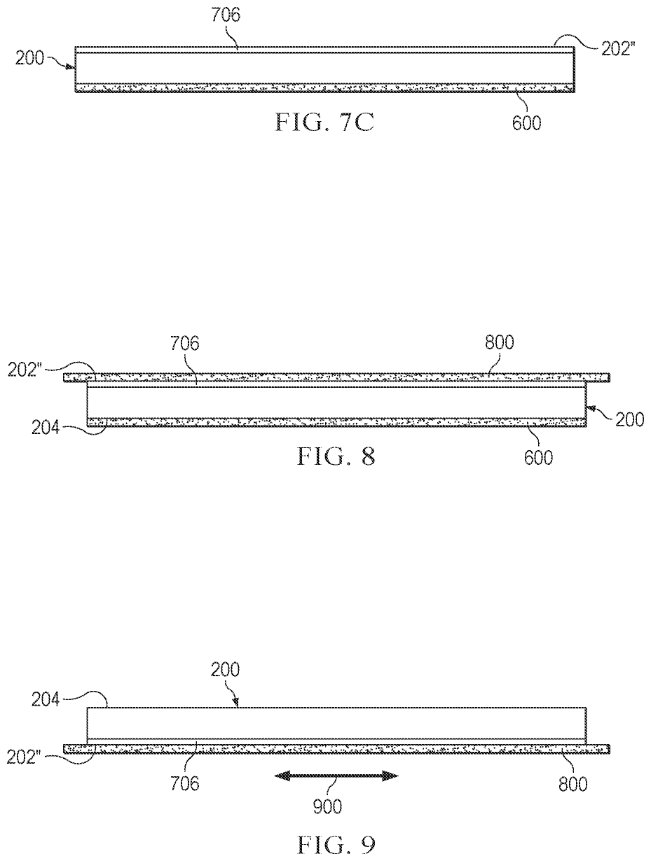

After testing has been completed, the method proceeds to 112, in which backgrind tape is applied to the frontside surface of the substrate. For example, as shown in FIG. 6, a UV curable backgrind tape 600 is applied to the frontside surface 204. At 114, the method includes thinning (e.g., backgrinding) the backside of the substrate to separate the dies. For example, as shown in FIG. 7A, the wafer 200 is mounted on a stage 700 after the tape 600 has been applied to the frontside surface 204, as shown in FIG. 6. The stage 700 can be moveable in two or more orthogonal directions parallel to the surface of the wafer 200 (e.g., to provide movement in five degrees of freedom). FIG. 7A also shows a surface grinder 702 having a rotating grinding wheel 704 supported above the stage 700 and configured to thin the substrate by grinding and/or polishing. The grinder 702 can be the same or different grinder from the grinder 302 used at 104 for pre-grinding. At 114, the grinder 702 is thus configured to remove a portion of the substrate by grinding the first side surface 202′ to a depth sufficient to separate the dies from one another along the respective scribe streets. For example, the grind platform is configured to control the grinding to deeper within the modified region 416 (e.g., a silicon damage (SD) layer) within the substrate (e.g., silicon) than existing approaches. The grind height and other grind parameters can also be controlled to form an additional layer 706 on the backside of each die of the wafer (see, e.g., layer 1016 of the die in FIG. 10). The layer 706 can provide a standoff gap between the surface 202″ and the respective modified regions 416. As a result of the thinning at 114, the wafer 220 is provided a further thinned first surface, shown at 202″ in FIGS. 7B and 7C. FIG. 7C shows the semiconductor wafer after the backgrinding has been implemented at 114. In an example, the grinding at 104 implemented at 114 removes at least 50% (e.g., up to approximately 90%) of the thickness of the substrate from the backside (e.g., the backside 202′ previously thinned at 104) of the wafer 200. For example, the grinder 702 is configured to implement backgrinding so that the resulting surface 202″ extends through the modified regions 416, such as shown in FIG. 7B. Referring to FIGS. 4 and 7B, for example, the backgrinding removes a portion of the semiconductor substrate that include the cracks 422 in the semiconductor substrate extending between the backside 202′ and the modified regions 416. The backgrinding can also thin partly into the modified regions 416 to provide the further thinned surface 202″ as shown in FIGS. 7B and 7C.

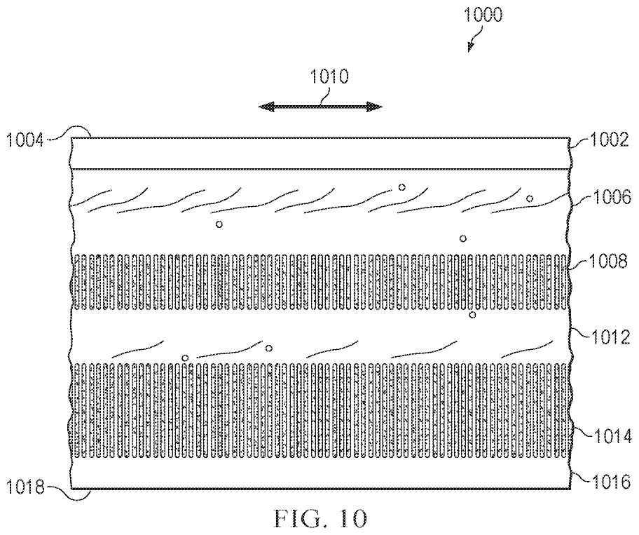

Referring back to FIG. 1, at 116, the method includes applying a dicing tape to the backside of the substrate that was thinned at 114. For example, as shown in FIG. 8, dicing tape 800 is applied to the backside surface 202″ opposite the backgrind tape 600. For example, the dicing tape 800 is an integrated tape structure having a backing layer, such as can be made of Polyvinyl chloride (PVC), polyolefin, or polyethylene backing material, and an adhesive to hold the wafer 200 in place during expansion. After the dicing tape is applied, at 118, the backgrind tape can be removed from the frontside surface 204, and the dicing tape will hold the singulated die in place, such as shown in FIG. 9. At 120, the substrate is expanded to space the dies further apart from one another by a distance (e.g., a known distance). For example, as shown schematically in FIG. 9, the dicing tape 800 holds the already-singulated die in place as the substrate 200 is expanded uniformly in orthogonal directions (e.g., including as shown by arrow 900 and another direction—not shown—orthogonal to the arrow 900 and the surface of the drawings sheet). The directions of expansion thus are parallel to the backside surface and are orthogonal to the directions of the respective scribe streets, such as to space the respective dies apart along the scribe street by a desired die-to-die gap. Expansion is facilitated at 120 because the dies have already been separated from one another along the respective scribe streets by the backgrinding at 114. The separated dies can remain on the dicing tape and be picked up (e.g., by a pick-and-place device) for further processing.

In an example, further processing can include picking up respective die can be picked from the dicing tape 800 and physically attaching the die to a leadframe using a die attach material (e.g., epoxy attach, eutectic solder attach, or glass frit attach). In some examples, wire bonding can be utilized to connect leads on the die surface to respective terminals of the leadframe. The resulting die assembly can be packaged (e.g., encapsulated) in a molding material. The molding material can be any suitable IC chip packaging material, such as a plastic material or ceramic material, to provide a packaged semiconductor device. The method of FIG. 1 can be used to produce a device according to virtually any packaging technology, including a wafer chip scale package, chip scale package or other package type.

FIG. 10 is a side view showing a sidewall of a singulated die 1000, such as produced by the method of FIG. 1. As shown in FIG. 10, the sidewall of the die has different surface textures as a result of using backgrinding to singulate the dies as described herein. In the example of FIG. 10, the die has a frontside surface layer 1002 that extends from a frontside surface 1004 a depth into the die 1000. The layer 1002 can contain some or all of the IC formed on the die. A next layer 1006 show a surface where a crack was formed extending from the layer 1002 to a silicon damage (SD) layer 1008 toward the surface 1004. The SD layer 1008 exhibits a rough texture such as in the form of ribs or other features extending longitudinally in a direction between adjacent layers 1006 and 1008. The texture shown in the layer 1008 is representative of focusing the laser beam within a scribe street during laser dicing (e.g., stealth laser dicing at 106 of FIG. 1) to form the SD layer 1008. For example, the respective ribbed texture can be formed by corresponding pulses of the laser beam that are generated as the beam is moved in a direction, shown as 1010, parallel to a longitudinal direction of a scribe street of the wafer. A layer 1012 represents part of the die sidewall surface where another crack was formed in the scribe street extending from the SD layer 1008 to another SD layer 1014. In the example of FIG. 10, the SD layer 1014 exhibits a rough ribbed texture like layer 1008, however, the layer 1014 is wider (e.g., in a direction orthogonal to surfaces 1004 and 1018 of the die 1000) than the layer 1008, such as due to providing the laser beam with a greater power focused within the area of the layer 1014 than the laser beam used to form the layer 1008. A backside layer 1016 (e.g., representative of layer 706 in FIGS. 7B and 7C) extends between the SD layer 1014 and a backside surface 1018 of the die 1000. The backside 1016 layer thus provides a gap (e.g., a silicon standoff gap) between the SD layer 1014 and the surface 1018. For example, the backside layer 1016 is separated during the grinding (e.g., backgrinding at 114) as the grind force extends the cracks from the SD layer 1014. For example, during the backgrinding at 114 the grind height can be controlled to form the layer 1016 on the backside of the die 1000.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. A method, comprising:
thinning a first side of a semiconductor substrate, in which a plurality of dies are formed on a second side of the substrate opposite the first side and separated from each other by scribe streets of the substrate;
directing a laser beam at the first side with an entry point along a scribe street thereof, in which the laser beam is focused inside the substrate to form at least one modified region within the substrate at a location spaced apart from the first side and at least one crack propagates from the modified region toward the first side; and
electrically testing the dies on the substrate, in which the dies being tested are located between modified regions of respective scribe streets of the substrate.

2. The method of claim 1, wherein the substrate has a thickness and the thinning includes backgrinding to remove less than 10% of the thickness of the substrate from the first side of the substrate.

3. The method of claim 1, further comprising removing tape from the second side of the substrate after directing the laser beam and prior to testing the dies.

4. The method of claim 1, wherein the substrate has a thickness, the thinning is a first thinning prior to directing the laser beam, and the method further comprises:
second thinning the first side of the substrate to reduce the thickness of the substrate and separate the dies along the modified regions in the scribe streets.

5. The method of claim 4, wherein the second thinning includes backgrinding to remove at least 50% of the thickness of the substrate.

6. The method of claim 5, wherein the backgrinding removes a portion of the substrate sufficient to remove cracks in the substrate between the first side and the modified region.

7. The method of claim 4, further comprising:
applying a first tape to the second side of the substrate prior to the second thinning; and
applying a second tape to the first side of the substrate after the second thinning.

8. The method of claim 7, further comprising:
removing the first tape from the second side of the substrate; and
expanding the substrate using the second tape to space the separated dies apart from one another by a distance.

9. A semiconductor device including a die produced according to the method of claim 1, wherein:
the die has a first surface on the first side, a second surface on the second side and respective sidewall surfaces extending between the first and second surfaces, and a first surface region of the sidewalls extending from the first surface to an intermediate location has a modified texture responsive to separating adjacent dies through the modified region and a second surface region extending from the intermediate location toward the second surface has a different texture responsive to separating adjacent dies through a crack.

10. A method, comprising:
directing a laser beam at a first surface of a semiconductor substrate with an entry point along a scribe street thereof, in which the laser beam is focused inside the substrate to form at least one modified region within a respective layer of the substrate at a location spaced apart from the first surface and at least one crack propagates from the modified region toward the first surface;
removing tape from a second surface of the substrate that is opposite the first surface, and
electrically testing a plurality of dies on the substrate, in which the dies being tested are located between modified regions of respective scribe streets of the substrate.

11. The method of claim 10, further comprising thinning the substrate from the first surface to reduce a thickness of the substrate and separate the dies along the modified regions in the scribe streets and provide a thinned first surface.

12. The method of claim 11, wherein the thinning includes backgrinding to remove at least 50% of the thickness of the substrate from the first surface.

13. The method of claim 12, wherein the backgrinding thins the substrate by an amount sufficient to provide the thinned first surface within the modified region.

14. The method of claim 11, further comprising:
applying a first tape to the second surface of the substrate prior to the thinning; and
applying a second tape to the first surface of the substrate after the thinning.

15. The method of claim 14, further comprising:
removing the first tape from the second side of the substrate; and
expanding the substrate using the second tape to space the separated dies apart from one another by a distance.

16. A semiconductor device including a die produced according to the method of claim 11, wherein:
the die has a first die surface on the first side, a second die surface on the second side and respective sidewall surfaces extending between the first and second die surfaces, and
a surface region of the sidewalls extending from the first die surface has a modified texture responsive to separating adjacent dies through the modified region.

17. The method of claim 10, wherein the prior to directing the laser beam, the method comprises thinning the first side of the substrate.

18. The method of claim 17, wherein the substrate has a thickness and the thinning includes backgrinding to remove less than 10% of the thickness of the substrate from the first side of the substrate.

19. A semiconductor device, comprising:
a semiconductor die including an integrated circuit in a semiconductor substrate, in which the semiconductor die has a sidewall extending between the first and second surfaces, a first surface region of the sidewalls extending from the first surface to an intermediate location has a first texture, and a second surface region extending from the intermediate location toward the second surface has a second texture that is smoother than the first texture.

20. The semiconductor device of claim 19, wherein the first texture is responsive to separating the semiconductor die through a modified portion of the substrate and the second texture is responsive to separating the semiconductor die from an adjacent die through a crack.
